(19) United States
(12) Patent Application Publication
(10) Pub. No.: US 2010/0300530 A1
(43) Pub. Date: Dec. 2, 2010

(54) Flagella as a Biological Material for Nanostructured Devices

(76) Inventors: MinJun Kim, Philadelphia, PA (US); William R. Hesse, Lebanon, NJ (US); Rafael Mulero, Newark, DE (US); Langli Luo, Vestal, NY (US); Junghyun Cho, Vestal, NY (US)

Correspondence Address: WOODCOCK WASHBURN LLP, CIRA CENTRE, 12TH FLOOR, 2929 ARCH STREET, PHILADELPHIA, PA, 19104-2891, US

(21) Appl. No.: 12/764,205

(22) Filed: Apr. 21, 2010

Related U.S. Application Data
(60) Provisional application No. 61/171,146, filed on Apr. 21, 2009.

(51) Int. Cl. H01L 31/04; A61K 9/14; B05D 3/00; B32B 5/00

(52) U.S. Cl. 136/257; 424/489; 427/398.1; 428/357; 977/700; 977/762; 977/948; 977/795

(57) ABSTRACT

Provided are nanoscale, mineralized structures from naturally-occurring materials and related methods for manufacturing these structures. The structures are useful in construction of photovoltaic devices and sensor applications.

### RELATED APPLICATIONS

This application claims the benefit of U.S. application Ser. No. 61/171,146, filed on Apr. 21, 2009, the entirety of which is incorporated herein by reference for all purposes.

### STATEMENT OF GOVERNMENT RIGHTS

This invention was made with government support under grant no. CMMI 0745019 awarded by the National Science Foundation (NSF). The government has certain rights in this invention.

### TECHNICAL FIELD

The present invention relates to the field of mineralized nanostructures and to the field of photovoltaic devices.

### BACKGROUND

Because of their useful properties, nanoscale structures are attracting interest in a variety of fields. Biological templates have received great attention due to their ability to self assemble, and viruses, such as the Tobacco Mosaic Virus and the M13 virus, as useful as templates for the formation of nanowires. There is accordingly interest an in the field in methods and devices that take advantage of the self-assembling properties of naturally-occurring materials. The value of such methods and devices would be further enhanced if the methods and devices had use in a broad range of applications.

### SUMMARY

In meeting the described challenges, first provided are method of fabricating mineralized nanostructures, the methods comprising disposing a metal oxide along at least a portion of a flagellar filament derived from a bacterial flagellum.

Also provided are nanostructures, comprising a nanostructure comprising a characteristic cross-sectional dimension in the range of at least about 40 nm, and the nanostructure comprising at least one mineralized region.

The present invention also discloses photovoltaic devices, the devices comprising a plurality of nanostructures, the nanostructures being in electrical communication with a first electrode; a dye capable of photoexcitation in electrical communication with one or more of the nanostructures; a second electrode; and an electrolyte disposed between the first and second electrodes so as to place the first and second electrodes in electrical communication with one another.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. In the drawings:

FIG. 1 illustrates an exemplary Flagella isolation procedure. S. typhimurium is cultured in LB broth (a) for 16 hours with constant shaking for aeration. The cells are then centrifuged to rinse and are then resuspended in motility buffer to concentrate the cells, which steps are repeated and the cells are resuspended (b) in saline solution. The pH of the solution is adjusted to 2 with HCl, which depolymerizes the flagella from the bacteria (c) into flagellin. The cell bodies are sedimented (d) with centrifugation and removed. 2M Na₂SO₄ is added so a small volume of flagellin to polymerize small flagella fragments (e) to be used as seeds for the polymerization of long flagella filaments. The flagella seeds and remaining flagellin (f) are mixed and incubated at room temperature for 24 hours to repolymerized the flagella into long filaments (g);

FIG. 2 depicts (A) fluorescently labeled flagella filaments, and (B) SEM micrographs of bare flagella;

FIG. 3 depicts length distribution of repolymerized flagella—220 fluorescently labeled flagella filaments were measured. The average filament length was found to be 6.2±2.5 μm (mean±standard deviation), and was fit to a Poisson distribution;

FIG. 4 depicts SEM micrographs of amorphous TiO₂ thin film (which may be termed a ‘gel’) covered flagella at various magnifications;

FIG. 5 depicts SEM Micrographs of TiO₂ particle thin film covered flagella filaments;

FIG. 6 depicts SEM micrographs of annealed TiO₂ thin film covered flagella filament: (A) after annealing at 400° C., (B) after annealing at 200° C.

FIG. 7 depicts an overview of the various steps in the disclosed processes for manufacturing mineralized nanostructures;

Table 1 presents nanotube characteristics as a function of various processing conditions;

FIG. 8 depicts the operation of a flagella template dye-sensitized solar cell;

FIG. 9 depicts a schematic of the fabrication process flow diagram for a photovoltaic cell. (a) The device starts with a cleaned Fluorine-doped Tin Oxide transparent conducting oxide (TCO) as the substrate, (b) A self-assembled monolayer (SAM) of Octadecyltrichlorosilane (OTS) is assembled on the FTO, (c) The OTS SAM is etched with focused ion beam (FIB) lithography. The FIB creates 50 nm holes in the OTS to accommodate flagella. (d) Biotin is immobilized on the substrate, (e) Ferrocene-avidin is immobilized on the substrate by highly specific binding with biotin, and the ferrocene modified avidin is to create good electrical connection from the flagella to the substrate, (f) platinum is deposited on the platinum counter electrode by evaporation to create a catalytically rich surface, (g) the single end biotinylated flagella immobilized on the substrate via highly specific binding with ferrocene-avidin. An electric field is used to orient the flagella in the correct direction, (h) the flagella are sensitized with dye, (i) the device is assembled by sealing three sides with hot melt spacers. The electrolyte is then added and the fourth side is sealed to finish the device; and the electrolyte is then added and the fourth side is sealed to finish the device;

FIG. 10 depicts (Left) a SEM micrograph showing the morphology of the ZnO nanoneedle array formed on the layered ZnO buffer/Pt/Si substrate by catalyst free MOCVD, and (Right) emission current densities obtained from the series of measurements on the ZnO nanoneedle array FE cell;

FIG. 11 depicts (Left) a method for the preparation of flagellar filaments: (a) bacteria are grown for 10 hours in LB broth; (b) centrifuged and resuspended in PBS; (c) vortexed to separate flagellar filaments; (d) bacterial cell bodies are pelleted by ultracentrifugation; (e) the supernatant is resuspended in PBS; (f) the flagellar filaments are broken into smaller pieces by sonication; (g) depolymerized by heating; (h) the seeds are added to the solution of flagellin and repolymerization is carried out for 24 hours. (Right) Optical micrograph of fluorescently-labeled flagellar filaments repolymerized from S. typhimurium; and

FIG. 12 depicts a schematic of back-gate type field-effect transistors (FET) according to the present invention, with (a) flagellar nanotube and (b) flagella-templated zinc oxide nanotube.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

In a first embodiment, provided are methods of fabricating a mineralized nanostructures. These methods suitably include disposing a metal oxide (e.g., TiO₂) along at least a portion of a flagellar filament derived from a bacterial flagellum.

In some embodiments, the methods further include annealing the metal oxide at a temperature less than about 100° C., of less than about 200° C., less than about 400° C., or even less than about 600° C.

The flagellar filaments used in the present invention are suitably grown by polymerization of flagellin monomers, as is described elsewhere herein. The monomers are obtained—as is described elsewhere in this application—by, for example, deflagellating bacterial cells by acid treatment and then centrifuging the recovered flagellae.

The monomers are suitably contacted with one or more flagellar fragments, which fragments may be obtained from bacterial flagella. The flagellar filaments are suitably obtained without introducing genetic modification to the flagellae.

Disposition of the metal oxide is suitably accomplished by reacting a precursor to the metal oxide in the presence of the filament. In some embodiments, the precursor undergoes a hydrolysis-condensation reaction, particularly where the precursor is a metal halide. Titanium chloride (TiCl₄) is considered particularly suitable where formation of titanium oxide along the flagellar filament is desired. TiOSO₄, TiF₄, M₂TiF₆ (M=Li, Na, K, Rb, Cs, and NH₄), SnCl₄, ZrCl₄, and the like are all considered suitable, and the user of ordinary skill will encounter little difficulty in finding the optimal metal-halide. For applications where, for example, tin oxide is desired, SnCl₄ is a useful precursor material. Zinc oxide, titanium dioxide, tin dioxide, silicon dioxide, zirconium oxide, tin oxide, iron oxide, apatite, and the like are also suitable materials for disposition on the flagellar filaments.

The disposition of the metal oxide is suitably performed between about 10° C. and about 90° C., or between about 25° C. and about 70° C., or even between about 40° C. and about 65° C.

The methods suitably give rise to a film of metal oxide disposed on at least a portion (or even all of) the filament. The inventive methods can, where desired, be used to deposit multiple films on a filament. Such multiple films can be accomplished by repeating the deposition steps described herein. The multiple films may be applied to different parts of the filament so as to give rise to different parts of the filament being surmounted by different films, or may be applied so as to dispose multiple films atop one another.

The methods also include the conversion of at least a portion of the film to a particulate form, as well as decomposing the filament. Filament decomposition is suitably performed by heating, by treatment with acid, or any combination thereof. Heating-based decomposition is considered preferable, as it is easily controlled and effects what may be termed a “burning-out” of the filament so as to leave behind the metal oxide film structure. The heating is suitably accomplished by exposing the filament to heat supplied by an oven, a heater, or even by microwave energy.

Disposition of the metal oxide is suitably performed in an aqueous solution. Buffers, water, and other aqueous media are all considered suitable media. The pH of the medium may also be adjusted if necessary to effect the desired disposition of metal oxide.

The methods suitably give rise to a mineralized nanotubular structure. Such tubular structures are fabricated by, as described elsewhere herein, disposing metal oxide along at least a portion of the flagellar filament and then removing the filament so as to leave behind the mineralized tube. Nanostructures made according to the disclosed methods are also within the scope of the invention. While the disclosed methods are described as applied to flagellae, the methods are also suitably applied to other naturally-occurring monomers, polymers, or other structures.

Also provided are nanostructures. The disclosed nanostructures suitably include a characteristic cross-sectional dimension in the range of at least about 40 nm to about 500 nm, or from about 100 nm to about 300 nm, or even from about 150 nm to about 200 nm, and at least one mineralized region. The nanostructures can be microns in length—in embodiments based on polymerized flagellar monomers, the nanostructures can be 15, 50, 75, or even 100 microns in length. Sub-micron structures may also be produced by the claimed methods.

The nanostructures are suitably tubular in form. Other configurations are also within the scope of the invention, including discs, rods, braids, and the like. Such configurations may be effected by polymerizing a naturally-occurring monomer—such as flagellin—in a mold or under such conditions that the polymerization product is of the desired configuration. In some embodiments, the filament may itself be formed and then be molded, bent, or otherwise shaped to achieve the user's desired configuration.

In embodiments where the nanostructure is tubular, the structure suitably has an inner diameter in the range of from about 1 nm to about 400 nm, or in the range of from about 10 to about 20 nm. The tubular nanostructures also suitably have an external diameter in the range of from about 150 nm to about 400 nm, or in the range of from about 200 nm to about 300 nm, or even of about 250 nm.

In some embodiments, the nanostructures include one or more nanoparticles disposed within. Suitable nanoparticle materials include titanium dioxide, zinc oxide, tin dioxide, silicon dioxide, and the like. The mineralized region of the nanostructure may include one or more nanoparticles, a film, or both.

The mineralized region may also be characterized as a film. The film may include titanium dioxide, zinc oxide, tin dioxide, silicon dioxide, zirconium oxide iron oxides, apatite, and the like; other suitable materials are described elsewhere herein.

The disclosed nanostrucutures are suitable for drug containment and, in some cases, in drug delivery. In these embodiments, the nanostructures may include an active agent, a dye, a pharmaceutical, and the like, disposed or even encapsulated within the nanostructure. The agent, drug, or dye, may, in some embodiments, be bound reversibly (or permanently) to the nanostructure, depending on the user's needs. The drug or agent may be disposed within the nanostructure and then be sealed inside the nanostructure with a sealant (e.g., a polymer) that degrades upon delivery to a biological environment.

The disclosed tubular nanostructures are also useful in, for example, filtration devices. In such devices, there are suitably an inlet and an outlet in fluid communication with a tubular nanostructure according to the claimed invention. The filters may be used in isolating analytes of interest from a fluid, and the nanostructures may include one or more binding entities (e.g., antibodies, antigens, oligonucleotides, and the like) useful in separating an analyte from solution. The binding entities may be chosen so as to selectively remove one analyte from solution while leaving other analytes behind.

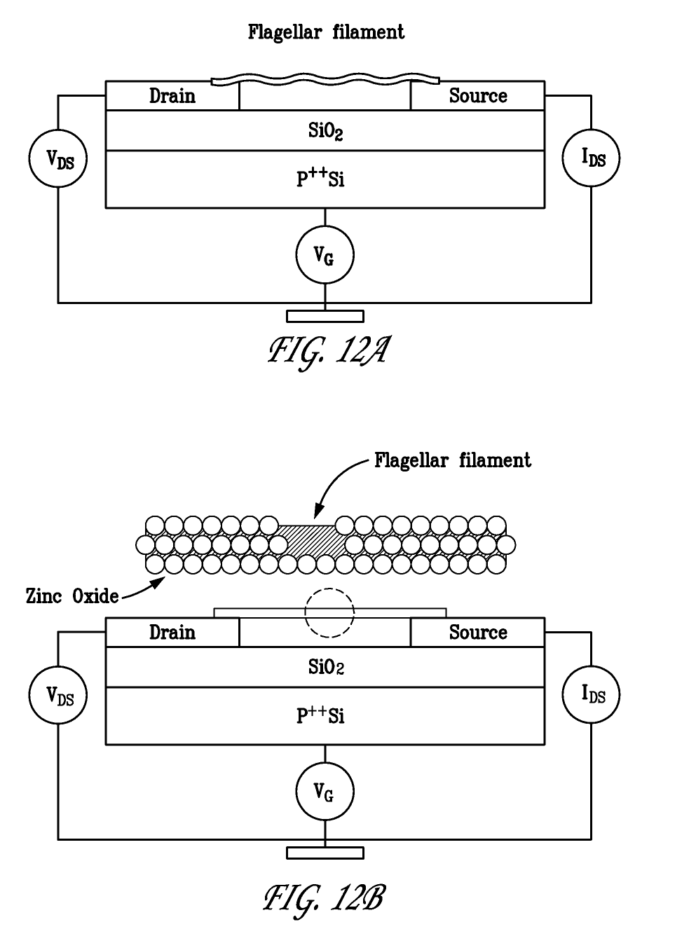

In other embodiments, the nanostructure is useful as a field-effect transistor. In these embodiments, the nanostructure is in electronic communication with a source electrode and a drain electrode, as shown in FIG. 12, and as described in additional detail elsewhere herein.

In some embodiments, the nanostructure includes a binding moiety bound to the nanostructure. Suitable binding moieties include antibodies, antigens, ligands, receptors, oligonucleotides, and the like. The nanostructures may be used as sensors; a change in an electrical property of the nanostructure caused by the binding of an analyte to the nanostructure may be monitored. For example, an antigen-bearing nanostructure mounted between two electrodes exhibits a change in an electrical property when a complementary antibody binds to that antigen, which change in electrical property (e.g., resistance, capacitance) could be monitored by the user.

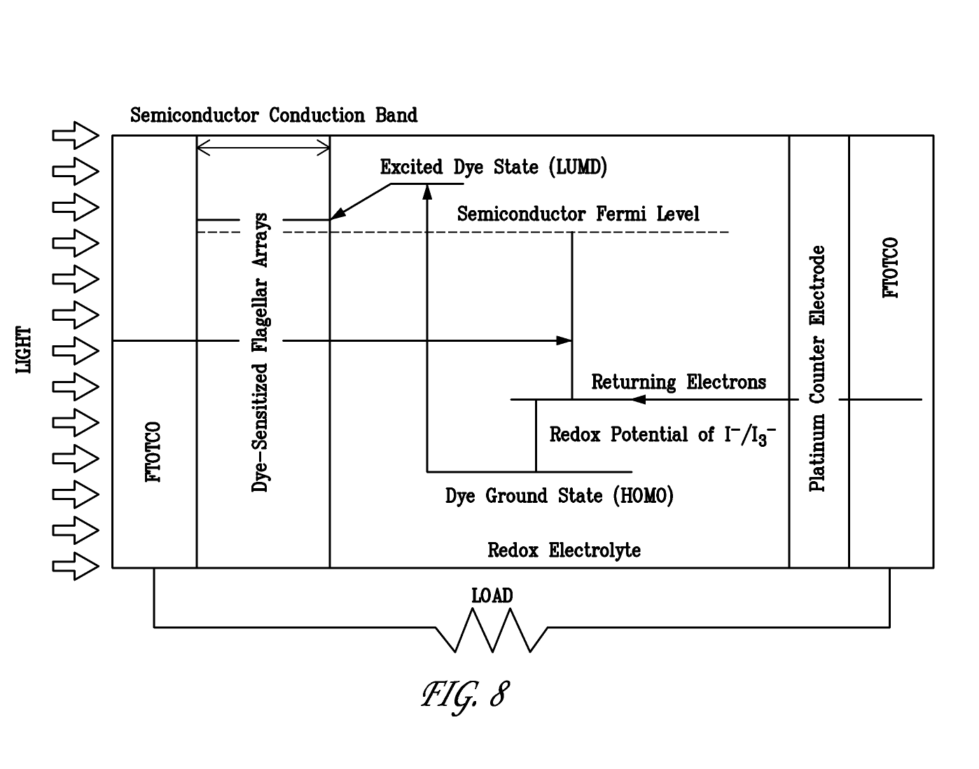

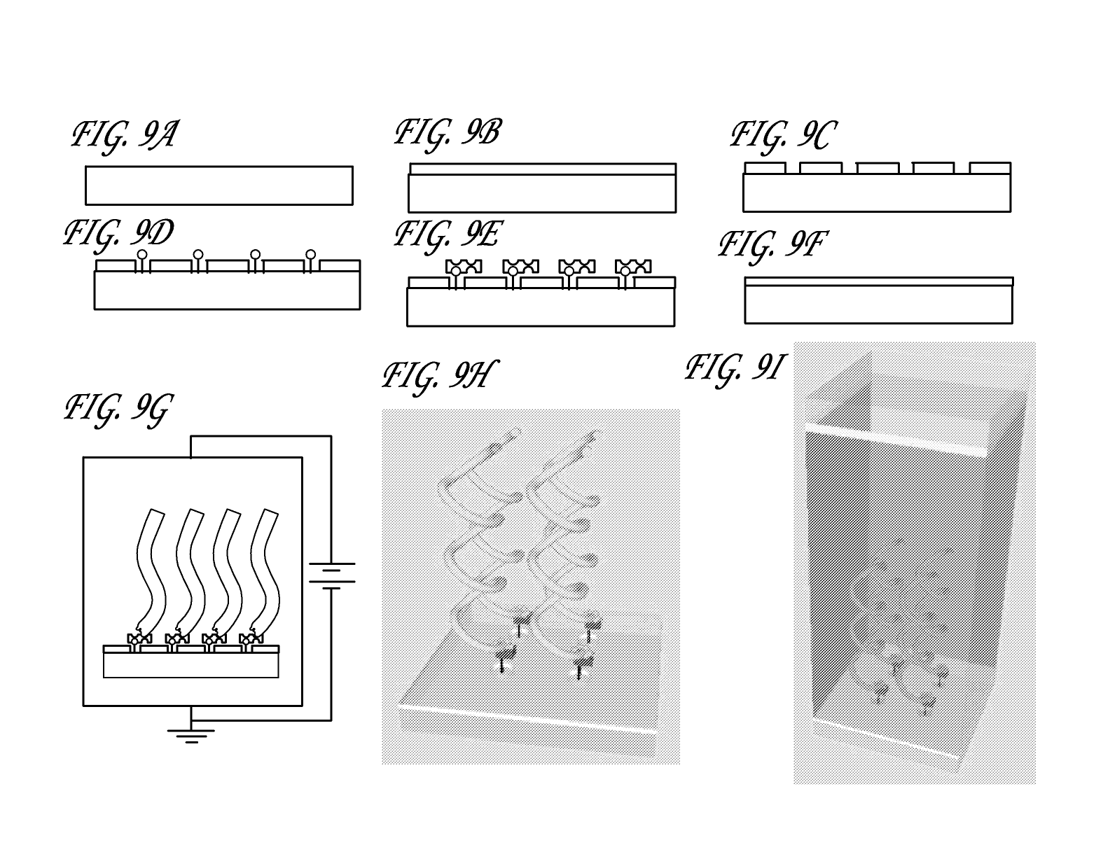

Also provided are photovoltaic devices, a exemplary embodiment of which is shown in FIG. 8 and FIG. 9. These devices suitably include one or more of nanostructures as described elsewhere herein, the nanostructures being in electrical communication with a first electrode. The photovoltaic devices also include a dye capable of photoexcitation, the dye being in electrical communication with one or more of the nanostructures. The devices also include a second electrode and an electrolyte disposed between the first and second electrodes so as to place the first and second electrodes in electrical communication with one another.

The invention also provides supported catalysts. These catalysts suitably include a nanostructure as described elsewhere herein, and one or more catalyst particles disposed adjacent to the nanostructure. The catalyst particles may be molybdenum sulfide, gold, platinum, or other catalytic metals and minerals known to those of skill in the art, including zeolites. Catalyst particles may comprise a single material or multiple materials.

Flagella Isolation and Mineralization

As known in the art, flagella are tubular structures that are helical in their natural polymorphic shape. Flagella, however, can also take on 11 different polymorphic shapes, which shapes include changes in the filaments' helical pitch, helical diameter, and length. Owing to their polymorphic shape change, flagella have the ability to change its length by a factor of three.

The outer diameter of a flagella filament can range from 12 to 25 nm, while the inner diameter is 2 nm. The small inside diameter tubular nature with of the flagella, similar to that of carbon nanotubes, could find use in single molecule sensors where the flagellar nanotube forms a highly stable and reproducible nanochannel for which to pass DNA or other molecules. The nanochannel may also be suitable for filtering or for filling with nanoparticles to impart unique characteristics onto the nanotubes. Flagella are very rigid with a Young's modulus on the order of 10 Pa.

The filaments are also very robust in a wide variety of conditions including pH 2-10, temperatures up to 60° C. (although depolymerization starts at approximately 38° C.), and in alcohols. The ability of flagella to polymerize in vitro to lengths up to about 75 μm makes them a suitable template for extremely high aspect ratio nanotubes for high surface area to volume ratios which are important to the advancement of nanotube dye sensitized solar cells. Titanium dioxide semiconducting nanowires also of interest to many applications in addition to solar cells, such as sensors, cell studies, photocatalysts, and catalyst supports.

Flagella were isolated and purified by adapting the methods used by Ibraham and Darnton. Salmonella Typhimurium (SJW 1103) was grown by adding a 1 ml aliquot of frozen S. Typhimurium to 1 liter of LB broth (1% NaCl [w/v], 1% Tryptone [w/v], 0.5% Yeast Extract [w/v]) and incubating for 16 hours at 33° C. with constant shaking to create a saturated culture. The saturated culture of S. Typhimurium was rinsed and resuspended to a volume of 60 ml in Motility buffer (10 mM potassium phosphate buffer, 67 mM NaCl, 10⁻⁴M EDTA, 0.002% (w/w) Tween 20) by centrifugation at 1,600 g for 30 minutes. The rinsed solution was then centrifuged at 1,600 g for 90 minutes and resuspended in 8 ml of saline solution (67 mM NaCl, 10⁻⁴ M EDTA, 0.002% (w/w) Tween 20). The pH of the solution was then reduced to about 2 with the addition of 1M HCl; other acids (or bases) may be used to adjust pH.

The bacteria were then stirred constantly for 30 minutes by vortexing at a moderate setting while maintaining the pH at about 2. The cell bodies, which were deflagellated by the acid treatment, were then pelleted out by centrifugation at 5,000 g for 30 minutes. The supernatant was centrifuged for 1 hour at 105,000 g and 4° C. to sediment small debris and material that is insoluble at a pH of 2.

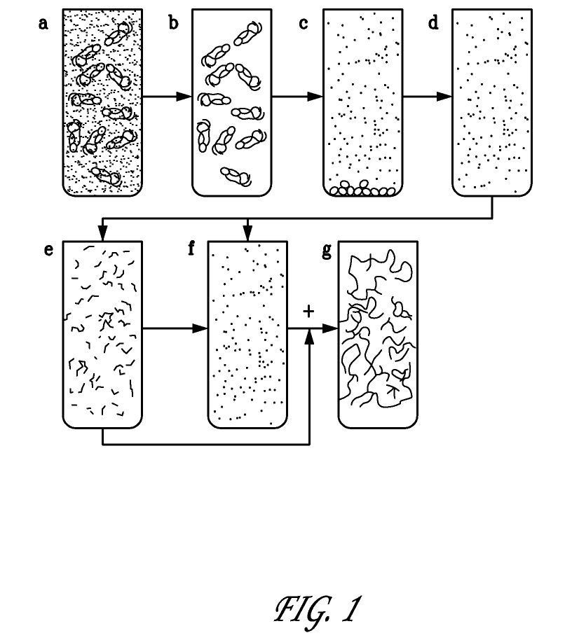

The resulting supernatant contained flagella monomers, the protein flagellin. A small portion of the monomer solution (1000 was removed and added to an equal volume of 2M Na₂SO₄, 10 mM Potassium Phosphate buffer (pH 6.5) to create polymerization seeds, which are small fragments of flagella that are used as nucleation sites for the polymerization of long flagellar filaments. The polymerization seeds were allowed to polymerize for 1 hour and then sedimented by centrifugation at 105,000 g for 1 hour and resuspended in 150 mM KCl, 10 mM Potassium Phosphate buffer (pH 6.5). The solutions of flagellin and seeds were combined and allowed to polymerize into long flagellar filaments for 24 hours. The process flow for the isolation of flagella is shown in FIG. 1. For storage, flagella were suspended in 150 mM KCl, 10 mM Potassium Phosphate buffer (pH 6.5) to a concentration of approximately 0.5 mg/ml (measured with BCA protein quantification assay (Pierce Rockford, Ill.), using BSA as a standard) and stored at either 4° C. or room temperature.

Flagella were imaged and characterized via fluorescent microscopy and the use of a field emission scanning electron microscope (FE-SEM). Repolymerized flagella were dyed with Cy3 dye (GE Life Sciences PA23001) and allowed to conjugate for 90 minutes with constant mixing at room temperature in the dark.

Excess dye was removed from the dyed flagella by filtering with a 0.2 μm syringe filter. A small drop was then placed on a microscope slide, covered with a coverslide then allowed to dry in the dark and viewed at 100× magnification with a Leica DMRB inverted microscope with N2.1 filter cube set.

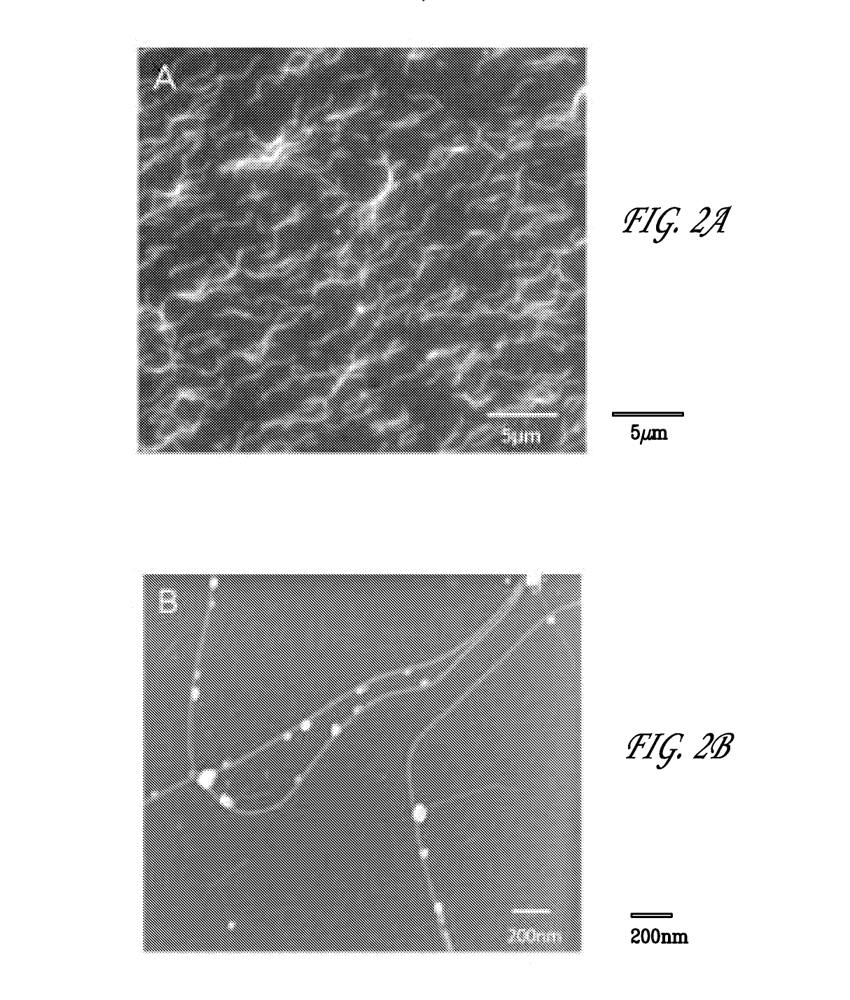

Flagella produced by the above method were analyzed to find a length distribution of the polymerized flagella. FIG. 2A shows fluorescently labeled filaments. Flagella were prepared for imaging with the SEM by placing a small drop of diluted flagella suspension was placed on a small silicon wafer substrate and dried at 70° C. in air. A thin layer of carbon film was deposited on the samples to avoid charging during SEM characterization. FE-SEM images were obtained with a Zeiss Supra 55 at 2 kV.

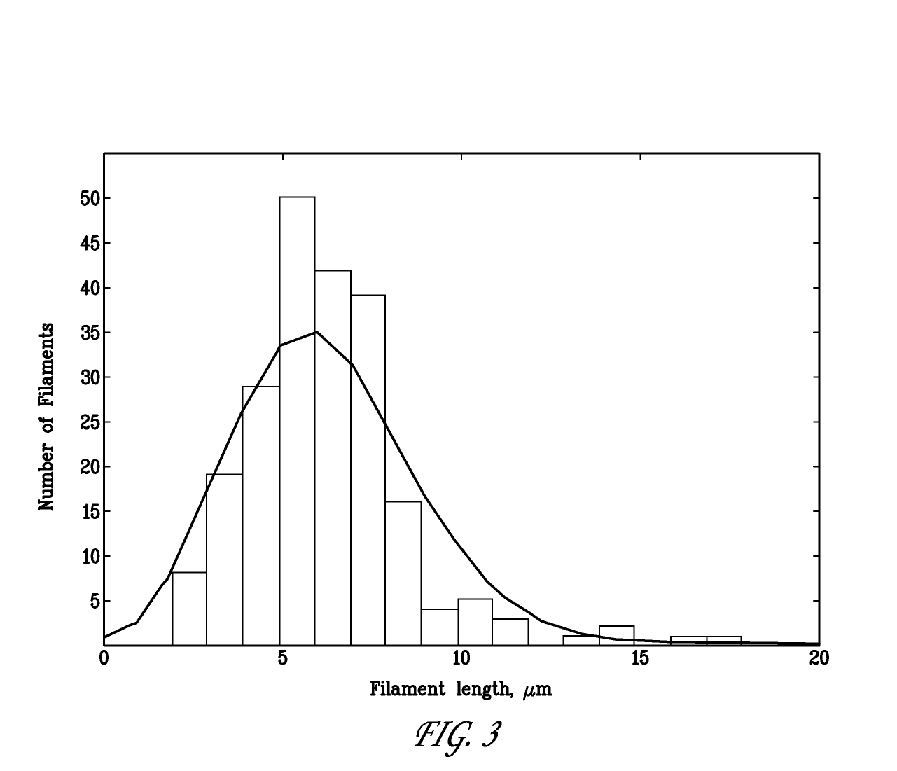

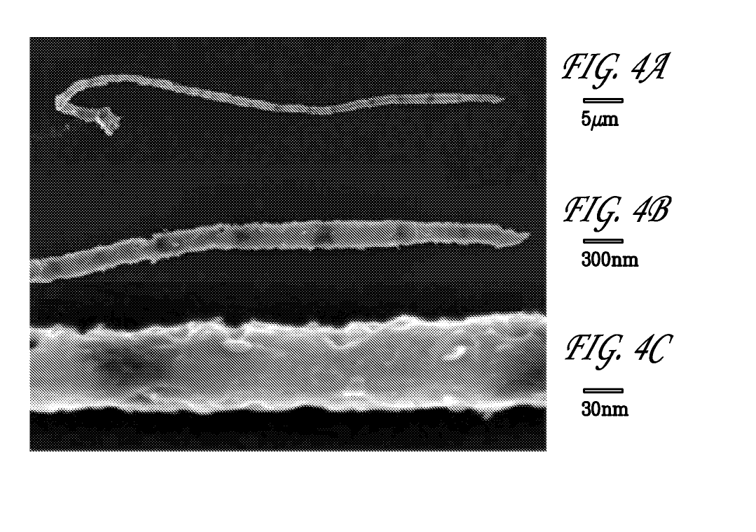

Flagella were found to have a diameter of about 30 nm and a length of a few to tens of microns, as shown in FIG. 2B. The small particles seen in this image are from the salt and buffer used in the storage solution. In addition, incomplete polymerized flagella were found with smaller lengths and diameters. These smaller filaments may be protofilaments, or linear polymers of flagellin, which have not been previously reported as being seen with repolymerized flagella filaments. The repolymerized flagella had an average length of about 6.2±2.5 μm. The length distribution generally followed the Poisson distribution, as seen in FIG. 3, which suggested that long flagella follow the Poisson distribution.

For ceramic thin film deposition on flagella filaments in aqueous solution, mild solution conditions (i.e., pH>2, solution temperature<60° C.) are required to preserve the flagella. There are various, naturally-occurring inorganic structures with a designed shape and size made by a biologically controlled biomineralization process, usually accomplished at near room temperature and in aqueous solutions. Further, biopolymers were shown to play a crucial role for the formation of biominerals.

To prepare mineralized nanotubes according to the claimed invention, a freshly prepared titanium chloride (TiCl₄, 99.99%, Alfa Aesar, Ward Hills, Mass.) aqueous solution (1 mM) was used as a precursor solution with a calibrated pH value of 2.5. The reconstituted flagella solution was ten times diluted then the diluted flagella and TiCl₄ solution were mixed with a volume ratio of 1:20 (flagella to TiCl₄). For deposition processing, a test tube of 10 mL mixed solution was kept at different temperatures for a varying time up to 60 minutes. For high-resolution SEM images, the solution with mineralized flagella filaments was first centrifuged at 5,000 g for 15 minutes, and then the supernatant was removed to eliminate impurities such as inorganic salts and dissolvable organic materials. The sediment was redissolved in distilled water and immediately dried by the same method for sample preparation of bare flagella filaments.

The hydrolysis of titanium chloride was vigorous, so a low concentration (1 mM) of titanium chloride was chosen for the precursor solution. Higher concentrations may be used, depending on process conditions. To analyze the effect of solution temperature on the hydrolysis and condensation reaction of TiCl₄ in the presence of the flagellar template, the temperature range from room temperature to about 70° C. was explored, although other temperatures are suitable for the present invention. Some transition in behavior occurred between 40° C. and 50° C.

Continuous amorphous TiO₂ film was deposited at 40° C. while nanoparticulate crystalline TiO₂ film was deposited at 50° C. on the flagellar surface. Due to the film deposition, the diameter of filaments increased up to 150 nm; films of greater diameter may also be formed.

FIG. 4 shows different magnifications of one amorphous TiO₂ covered flagella sample: in FIG. 4A, a whole filament in a length of 15 μm is clearly shown; even in higher magnification (4B and 4C) no clear structural development is visible on the filament surface. Without being bound to any single theory, the presence of long mineralized flagella demonstrates that the flagella are not degraded during processing.

Amorphous TiO₂ thin film may nucleate on the surface of the flagellar filament to that in solution due to a low activation energy barrier if it occurs on the former. The usual mineralized flagella do not have the same sinusoidal waveform of natural flagella. Without being bound to any particular theory, the straightening of the flagella may be due to solution conditions that induce a polymorphic shape change or due to the TiO₂ coating causing the flagella to straighten.

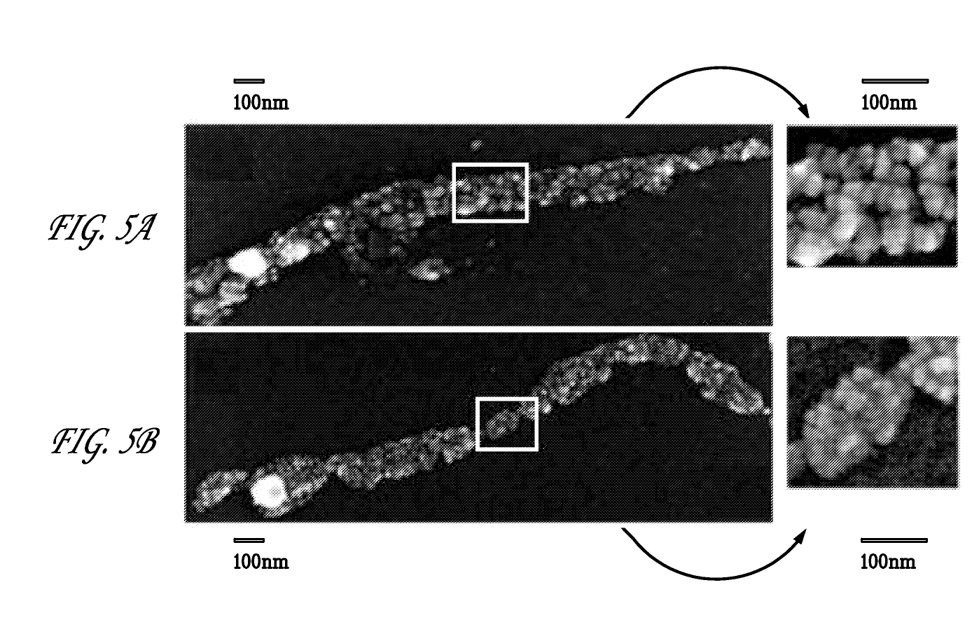

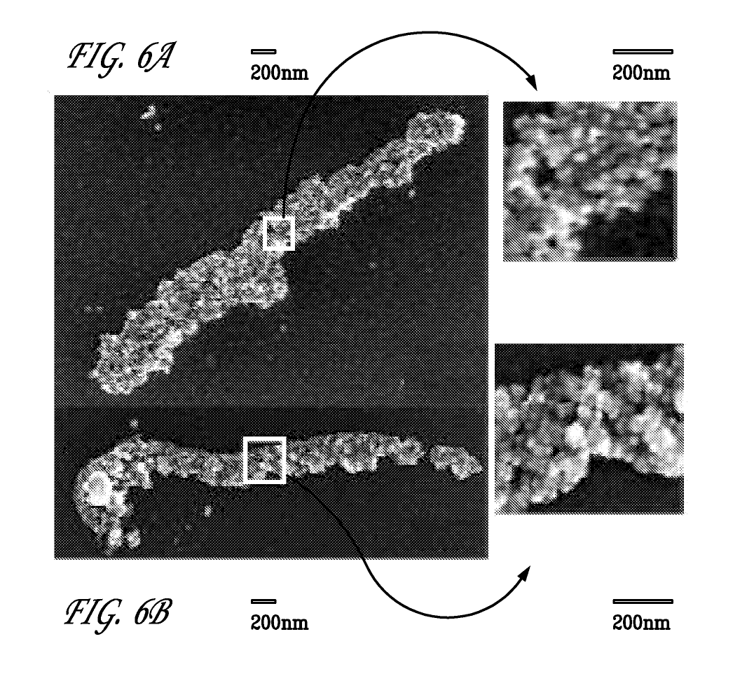

At higher temperature (50° C.), TiO₂ nanoparticles covered the surface of filament as shown in FIG. 5. The primary particle size ranged from 5-10 nm and the aggregate (secondary particle) size ranges from 30-40 nm (see figure insets). The average diameter of the mineralized filaments was found to be less than 100 nm. The size and shape of the particles are consistent with previous study that confirmed the particles were in an anatase phase.

While the TiO₂ particles are not perfectly uniformly distributed on the surface of filament, the surface area appeared to be covered with the TiO₂ nanoparticles formed through bulk precipitation (i.e., homogeneous nucleation).

Higher solution temperature promoted homogeneous nucleation of TiO₂ particles and strong interaction between the particles and the surface of the flagella due to electrostatic attraction. This interaction mechanism can be especially favorable because the flagella surface is negatively charged and TiO₂ particles (isolelectric point=4-6) are positively charged in the acidic solution condition (pH 2-3).

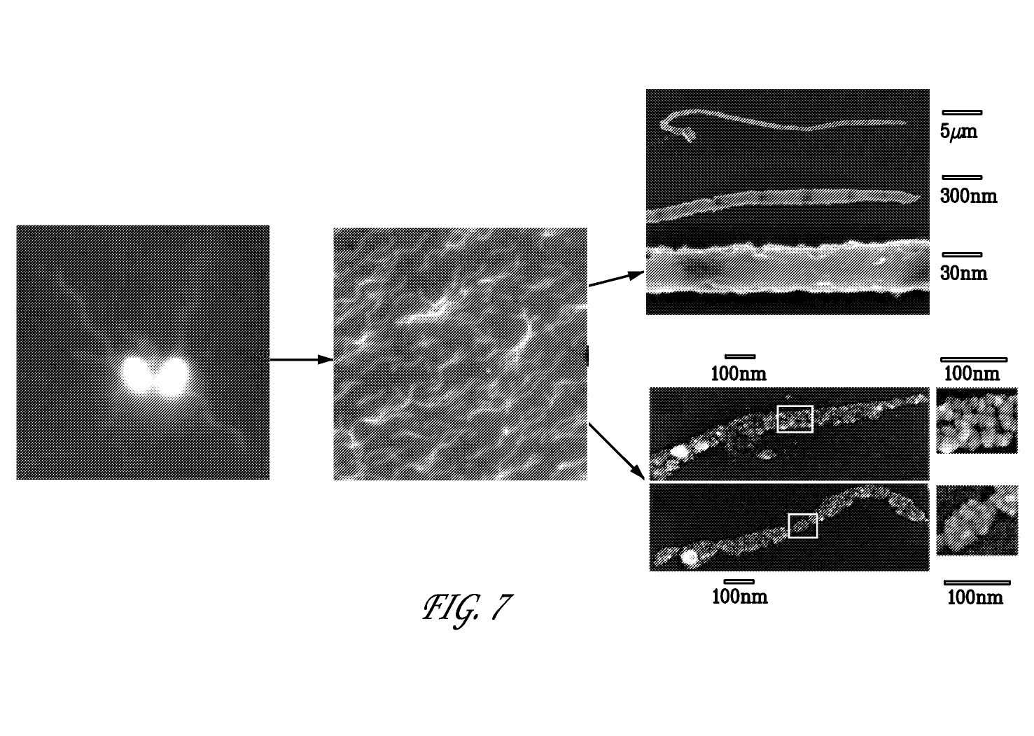

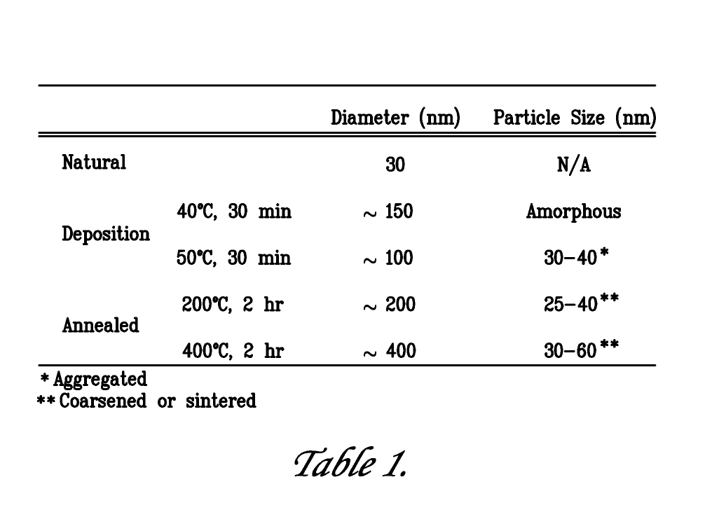

To observe the transition from amorphous to crystalline TiO₂, amorphous samples were annealed at 200° C. and 400° C. for 2 hours. After annealing, amorphous TiO₂ covered filaments disappeared; instead, nanoparticle TiO₂-covered filaments were observed. After 400° C. annealing, the densification of TiO₂ particles became more evident and displayed a larger diameter ˜400 nm of the filament. Without being bound to any particular theory, this may be been caused by the collapse of the mineralized filament (FIG. 6A). On the other hand, a lower annealing temperature, 200° C., resulted in a smaller filament diameter less than 200 nm (FIG. 6B), which is similar to those observed before annealing.

Annealing at 200° C. was sufficiently intense enough to decompose the flagellar filaments, leaving the inner core empty to generate the TiO₂ nanotubes. Nanotubes may also be generated through in-situ formation of TiO₂ nanoparticles deposited on the surface of the flagella in the precursor solution at temperatures over 50° C., followed by a heat treatment which can decompose the flagellar filaments. The method described herein to mineralize flagella has the advantage over other methods to deposit material on the flagella surface in that the flagella need not be genetically modified before the mineralization process.

Thus, disclosed is a useful process for the formation of TiO₂ nanotubes via templating of repolymerized flagella from S. typhimurium. The advantage with the method herein described is that is that this process can be done in laboratories without genetic sequencing tools because no genetic modification is necessary to prepare the flagella for specific interactions with a specified material.

TiO₂ is deposited on flagella via a biomimetic mineralization process where the material is deposited in aqueous solution. The processing environment is suitable for the use of flagella as a template without degradation. The processing conditions were found be very important to nanowire characteristics. Continuous amorphous phase TiO₂ was deposited at 40° C. while flagella coated in a thin film of TiO₂ nanocrystalline particles were created at 50° C. Annealing of the amorphous thin film nanowires generated nanotubes that were coated with nanoparticles, and the diameter of the nanotubes could be defined by the annealing temperature and time. Nanotubes made from a materials may thus be achieved by changing the precursor solution.

### ADDITIONAL BACKGROUND AND EXEMPLARY EMBODIMENTS

Field Emission Studies

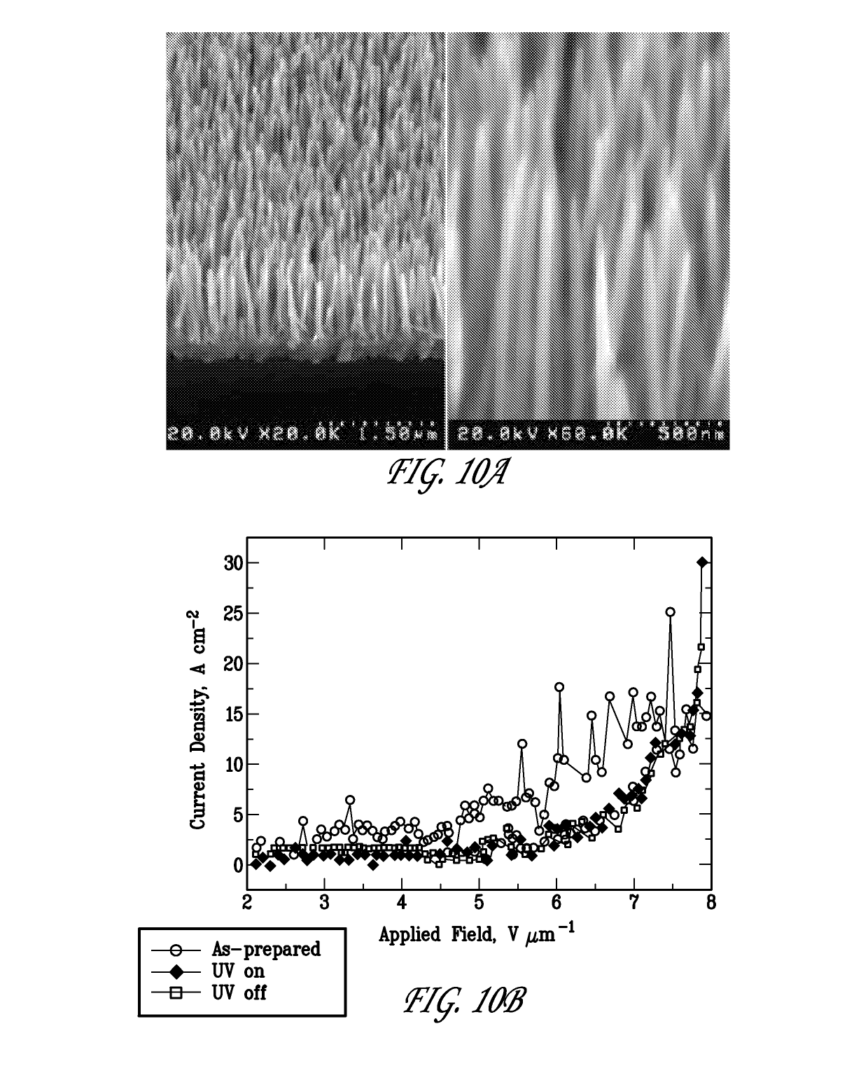

There is interest in the emission characteristics of ZnO nanoneedles grown by catalyst-free MOCVD from the viewpoint of the good vertical alignment and the role of oxygen-related surface species (FIG. 10). An array of ZnO nanoneedles was formed on Si (001) substrate deposited with ZnO/Pt buffer electrode first. Field emission characteristics were then measured on test FE cells with and without ultra-violet (UV) irradiation.

FE measurements on the as-prepared and the UV-treated ZnO nanoneedle array emitter cells showed that FE behavior of the nanoneedles is dependent on the UV-treatment, which is an indication that surface states induced by oxygen-related species have a significant effect of the FE characteristics of 1-D ZnO nanostructures. The effect of dimensionality and geometry on special materials properties are further investigated by the FE measurements to meet the demands of miniaturization and better performance of photovoltaic devices, as this emission property may suitably accomplish the conversion from solar energy to electronic emission for photonic electronic devices.

Harvesting Flagella

Also provided are novel methods to functionalize flagellar filaments for attachment within micro/nanostructures alone and in combination with other molecules or materials to be used for the formation of flagellar forests. Filaments are readily taken apart and reassembled in a stepwise process. Bacteria were grown and their filaments harvested by shearing; isolated by ultracentrifugation; depolymerized by heating to about 65° C.; repolymerized by adding seeds (short pieces of filaments created by sonicating isolated filaments) and then cooled. These filaments grow uni-directionally from one end of the seed, so it was straightforward to construct simple block copolymers by changing the kind of flagellin in the supernatant fraction of the buffer solution.

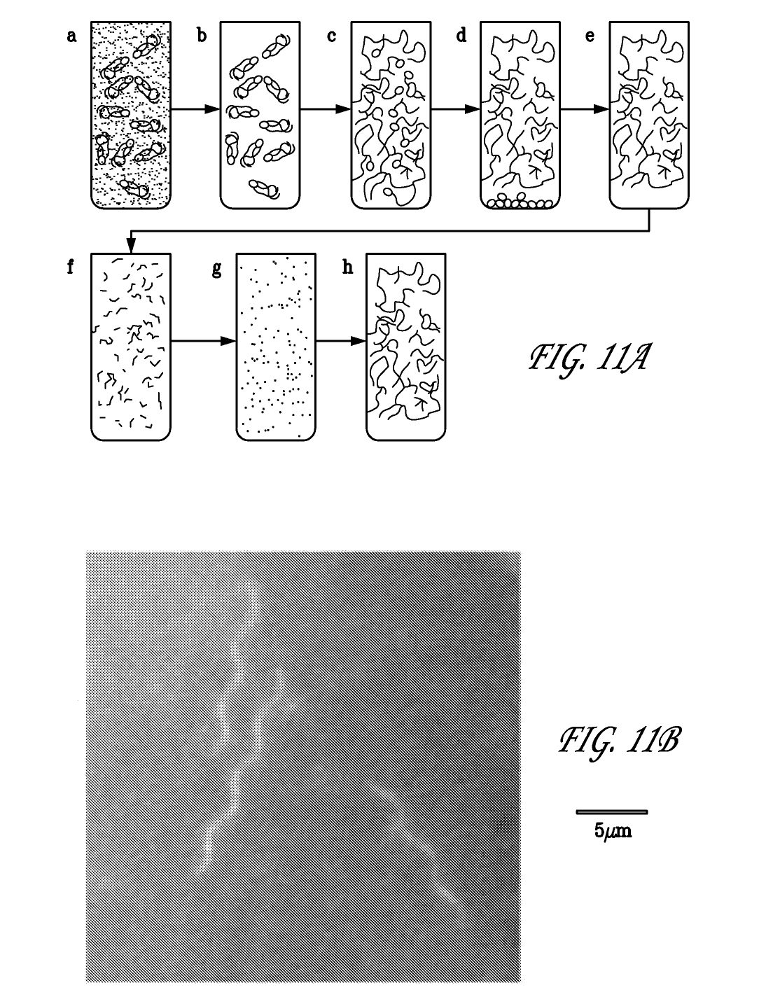

When filaments were detached from cells, they were generally shorter than about 10 μm (appx. 3 μm) and the distribution of lengths was broad. The filaments may also be repolymerized in vitro to give a length range of from about 10 to about 25 μm (e.g., FIG. 11), with some as long as 75 μm. Once made, the filaments were stable for extended times in polymerization buffer.

Flagellar Functionalization for Dye-Sensitized Solar Cells

Flagella were selected for use in the dye-sensitized solar cell due to their unique properties and the genetic modifications that can, if desired, be made to flagella to functionalize the material to suit the particular needs of the solar cell. S. typhimurium flagella are suitable for photovoltaic device design due to their well defined and studied polymorphic forms, but other strains of flagella may also be used—no aspect of the present invention should be understood as being limiting to any specific source of flagella.

Functionalization of the flagella also makes the positioning of the flagellar nanotubes on the substrate much more precise than is possible with current nanowire dye-sensitized solar cell devices. The poor control existing methods exert over the nanowire placement reduces the cells' performance.

Using bottom-up and topdown nanofabrication techniques, however, one may place the flagella exactly where they are desired. Highly ordered arrays forming a “flagellar forest,” can be created. Recently, several methods of mineralization have been used employing the M13 virus and the tobacco mosaic virus as organic protein templates. The M13 virus has been genetically modified to functionalize a subset of coating proteins for cobalt ion binding, and the tobacco mosaic virus has a natural set of functionalized proteins that allow for specific metal-ion biding through co-crystallization, oxidative hydrolysis, and sol-gel condensation. Thus, mineralization of these structures would enable the use of flagellar filaments as conductive nanotubes.

As previously described, a flagellum is composed of the protein, flagellin, organized in a helical structure with 11 proteins per turn. It has been found that the flagellin structure is broken into 4 sub-domains (D0, D1, D2, and D3, where part of D2 and D3 are the variable region). Genetically modified, zinc oxide template flagellar nanotubes may be created with the use of the Invitrogen (www.invitrongen.com) FliTrx protein expression systems, which partially substitutes the D2 and D3 domains of the flagellin (FliC) structure for the thioredoxin protein (TrxA).

Prior to the application of flagellar nanotubes, the field effect transistor (FET) is fabricated by a lift-off process. The drain and source electrodes used are made of gold/titanium placed on a 500 nm thick silicon dioxide insulating layer and have a channel width in range of 500 nm-5 μm, in which there is a hydrophilic attachment site. This is achieved by coating a gold substrate with a hydrophobic coating, and then lithographically etching the attachment site. The substrate will be immersed into a bath of flagella-templated nanotubes.

As the temperature is lowered, a nanotube will adhere to the substrate (chemical contact between the nanotube and the drain/source). The spacing and organization of the nanotube is determined solely by the lithography of the octadecyltrichlorosilane (OTS) coating described above. A heavily doped p++ Si substrate is suitably used as a back gate.

As the final step in flagellar nanotube FET preparation, the substrate is baked to improve contact resistance between the flagellar nanotube and electrodes. Atomic force microscopy (AFM) is useful to confirm features of nanotube bridging between the source-drain electrodes. The conductivity of the flagellar nanotube is suitably characterized by electrode deposition with e-beam lithography and direct electrical measurements for resistances and ohmic characteristics (FIG. 12).

A drain-source current (IDS) as a function of a drain-source voltage (VDS) or gate bias voltage (VG) will be measured using a four-point microprobe system. The PI will measure not only temperature dependence of current (IDS)—voltage (VDS) characteristics between the source-drain electrodes in vacuum surrounding but also the relationship between gate bias (VG) and IDS in order to investigate the polarity of the flagellar nanotube. The same experiments will be conducted, but with the application of a back-gate voltage to determine whether the flagellar nanotube acts as a p (hole dominant) or n (electron dominant)-type semiconducting material.

Photovoltaics

Another device provided by the present application is a flagella template dye-sensitized solar cell. These devices work by photoexciting dye molecules that in turn inject electrons into semiconducting scaffolds which then transport the electrons to the transparent conducting electrode (TCO), upon which incident light enters the device.

The dye chosen for this photovoltaic device is a ruthenium-based dye, (Bu4N)2Ru(dcbpyH)2(NCS)2(N719), used in other similar devices. The TCO chosen for this device is Fluorine doped Tin Oxide (FTO), although other transparent conducting electrode materials may be used. The dye scaffolds used in this device will be either bare flagella or nanotubes formed by the mineralization of the flagellar structure with zinc oxide. The flagella are used in place of zinc oxide nanowires so that the aspect ratio, and thusly, the surface area of the dye scaffolds increases. Put another way, the flagella are so long that the aspect ration of the flagella used in the “forest” is very favorable. This charge transfer mechanism shown in FIG. 8 requires that the redox electrolyte be oxidized so that an electron can be added to the photoexcited dye in order to bring the dye back to the ground state.

In the case of this solar cell, the mediator is the I-/13-redox couple, which has been shown to be the best known redox couple for this application. The load to be driven by the solar cell is placed between the TCO and is generally covered by platinum. Platinum is suitable due to its high electrocatalytic activity, which is necessary to reduce the redox electrolyte, although other metals may be used. This reduction of the redox electrolyte is used to return the oxidized redox electrolyte back to its normal state. The electrons that pass through the load and then end up on the platinum counter electrode are then transferred to the redox electrolyte which reduces the oxidized electrolyte.

A solar cell is fabricated by depositing OTS on the FTO TCO substrate to create a hydrophobic surface. Focused ion beam (FIB) etching is then sequentially employed to etch an array of 50 nm holes in the OTS layer to create hydrophilic openings that will be used for the immobilization of flagella on the TCO surface with the use of the biotin-avidin system. Flagella are prepared for immobilization by first harvesting high concentrations of flagella and then making flagella repolymerization seeds and monomers.

The seeds are biotinylated via sulfosuccinimidyl-6-[biotinamido]hexanotate from Pierce Chemical (EZ-Link-Sulfo-NHS-LC-Biotin, Rockford, Ill.) and then placed in solution with the monomers to initiate repolymerization of the flagella filaments. The depolymerization/repolymerization process is done so as to exert control over the filament length and thus aspect ratio.

After repolymerization, flagella exist as filaments with one functionalized end, which is used for immobilization on the TCO. The TCO with OTS monolayer is functionalized with biotin and then ferrocene-avidin immobilized on the TCO surface. Ferrocene-avidin, which was developed for biosensors making use of redox reactions is chosen because of the requirement of unimpeded electron transfer between the flagella dye scaffolds and the conducting substrate. The functionalized flagella are then immobilized on the TCO by placing the ferrocene-avidin modified electrode in a phosphate buffer solution and adding the flagella. The flagella are oriented in the vertical direction by the electric field and the biotinylated end of the flagella binds to the exposed ferrocene-avidin binding sites to create the “flagella forest.”

The solar cell is assembled by dye sensitizing the TCO with the “flagella forest” in a solution of the (Bu4N)2Ru(dcbpyH)2(NCS)2(N719) dye in dry ethanol. The platinum coated counter electrode, which is fabricated by evaporation onto an FTO electrode, and the dye-sensitized electrode are spaced apart with the use of hot melt spacers. The redox electrolyte (0.5M LiI, 50 mM I2, 0.5M 4-tertbutylpyridine in 3-methoxypropionitrile) is then added to the space between the two electrodes. FIG. 9 shows a schematic of the fabrication processes for flagella template dye-sensitized solar cells.

### Additional Information

In sum, provided are, inter alia, processes for the creation of flagellar nanotubes and the uses for these flagellar nanotubes. The process for the creation of flagellar nanotubes is a purely chemical method that uses acid to remove and depolymerize the flagella from its native form on bacteria into its constituent protein, flagellin, and then repolymerizing the flagellin into flagellar filaments of desired lengths. These uses include flagellar nanotubes for use as templates, sensors, actuators, and transporters. Field Effect Transistor (FET) devices may be created with the use of flagellar filaments to be used in sensing and discovery of the electrical characteristics of flagellar filaments.

The flagellar nanotubes may have the surface of the flagella modified in order to facilitate the specific binding with an analyte in solution, which will cause a change in the conductance of the flagella nanotube. Ordered arrays of flagella aligned vertically on a substrate to form a “flagella forest” will be used in photovoltaic and optics applications.

Photovoltaic devices based on zinc oxide mineralized flagella will be used in place of zinc oxide nanowires as extremely high surface area semiconductors in dye-sensitized solar cells. Flagella filaments are known to possess birefringent characteristics, which make them extremely valuable in optics applications. The flagella filament is known to change polymorphic shape, and thus length and helical diameter under varying electrical fields, which make the flagella filaments natural actuators that can be used to actuate micro/nanoswitches, micro-scale gear systems, and other devices for controlled drug delivery and micro-scale assembly.

The polymorphic transformations of flagellar filaments can also be used as pH, temperature or salinity sensors when combined with nanopore sensors. This is because as the helix changes shape with changing environmental conditions, the cross sectional area of the flagella passing through the nanopore changes, which causes a change in ionic current blockade signal.

As with other nanotubes, such as carbon nanotubes, flagellar filaments can be used as transporters for chemicals either by sequestration of particles within the helical structure or within the hollow tubule structure of the flagellar filament itself, which lends itself to drug delivery applications. Flagella are biocompatible materials, so biocompatibility is not an issue, unlike with other nanotubes.

Further advantages of flagellar nanotubes are that the nanotubes can be polymerized to lengths greater than is possible for mineral nanotubes and nanowires, or even for natural flagella sheared from bacterial cells. The disclosed method for the depolymerization of flagella from bacteria and repolymerization into flagellar filaments is advantageous in that it is a simple chemical process that does not leave cell body contaminants seen in mechanically derived methods.

The disclosed method for the formation of flagellar nanotubes also requires less special equipment than other procedures. Genetic or chemical engineering can be employed to easily customize the surface of the nanotube to act as either a conductor, semiconductor, or for binding to specific targets for use in sensing applications. The polymorphic transformations of the flagellar nanotubes are a great advantage that is lacking in other nanotubes. Under various physiological conditions, electrical field, mechanical force allow for the nanotubes to act as actuators and sensors either alone, or when combined with a nanopore to detect the change flagellar polymorphism. In medical applications, the flagellar filament has the advantage of biocompatibility over other nanotubes.

What is claimed:

1. A method of fabricating a mineralized nanostructure, comprising:
Disposing a metal oxide along at least a portion of a flagellar filament derived from a bacterial flagellum.

2. The method of claim 1, further comprising annealing the metal oxide at a temperature less than 100° C.

3. The method of claim 1, further comprising annealing the metal oxide at a temperature of at least about 600° C.

4. The method of claim 1, wherein the flagellar filament is grown by polymerization of flagellin monomers.

5. The method of claim 4, wherein the monomers are contacted with one or more flagellar fragments.

6. The method of claim 1, wherein the disposing is accomplished by reacting a precursor in the presence of the filament.

7. The method of claim 6, wherein the precursor is a metal halide.

8. The method of claim 7, wherein the precursor is TiCl₄, TiF₄, M₂TiF₆, SnCl₄, ZrCl₄, or any combination thereof.

9. The method of claim 1, wherein the disposing is performed at a temperature of between about 10° C. and about 90° C.

10. The method of claim 1, wherein the disposing gives rise to a film of metal oxide disposed on the filament.

11. The method of claim 1, further comprising decomposing the filament.

12. A nanostructure, comprising:
a nanostructure comprising a characteristic cross-sectional dimension in the range of at least about 40 nm, and
the nanostructure comprising at least one mineralized region.

13. The nanostructure of claim 12, wherein the nanostructure is characterized as tubular.

14. The nanostructure of claim 13, wherein the nanostructure comprises an inner diameter in the range of from about 1 nm to about 400 nm.

15. The nanostructure of claim 13, wherein the nanostructure comprises an external diameter in the range of from about 150 nm to about 400 nm.

16. The nanostructure of claim 12, further comprising one or more nanoparticles disposed within the tubular nanostructure.

17. The nanostructure of claim 12, wherein the mineralized region comprises one or more nanoparticles, a film, or both.

18. The nanostructure of claim 12, further comprising an active agent, a dye, a pharmaceutical, or any combination thereof, disposed within.

19. The nanostructure of claim 12, wherein the nanostructure is in electronic communication with a source electrode and a drain electrode

20. A photovoltaic device, comprising
a plurality of nanostructures according to claim 12,
the nanostructures being in electrical communication with a first electrode;
a dye capable of photoexcitation in electrical communication with one or more of the nanostructures;
a second electrode; and
an electrolyte disposed between the first and second electrodes so as to place the first and second electrodes in electrical communication with one another.
